(19) United States
(12) Patent Application Publication
(10) Pub. No.: US 2007/0117312 A1
(43) Pub. Date: May 24, 2007

(54) Method for fabricating capacitor of semiconductor device

(75) Inventor: Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/477,994

(22) Filed: Jun. 28, 2006

(30) Foreign Application Priority Data
Nov. 23, 2005 (KR) 2005-0112366

(51) Int. Cl. H01L 21/8242

(52) U.S. Cl. 438/253

(57) ABSTRACT

A method for fabricating a capacitor of a semiconductor device includes: forming a first insulation layer over a substrate; forming a plug in the first insulation layer to contact the substrate; forming an etch stop layer and a second insulation layer over a resultant structure obtained after forming the plug; etching the second insulation layer to expose a portion of the etch stop layer; oxidizing the exposed portion of the etch stop layer; removing the oxidized portion of the etch stop layer by a wet cleaning process to form a contact hole exposing the plug; and forming a storage node over the contact hole.

### FIELD OF THE INVENTION

The present invention relates to a method for fabricating a semiconductor device; and more particularly, to a method for fabricating a storage node contact hole of a semiconductor device.

### DESCRIPTION OF RELATED ARTS

In case of a storage node contact hole with a size less than approximately 90 nm, an etch margin of a photoresist pattern made of ArF is insufficiently secured by using a polysilicon layer as a hard mask. Accordingly, additional processes (i.e., a storage node contact hole key opening mask process, an etching process, and a storage node contact recess process) are required before and after defining a storage node contact hole. Also, the use of the photoresist pattern made of ArF increases cost.

Presently, when transforming a storage node contact hole type to a line type, the photoresist pattern made of ArF can be replaced by a photoresist pattern made of KrF and thus, a cost can be reduced. A chemical mechanical polishing (CMP) process is performed on an oxide layer to a bit line hard mask by using the photoresist pattern made of KrF and thus, a storage node contact plug is insulated.

FIGS. 1A and 1B are cross-sectional views illustrating a typical method for fabricating a capacitor of a semiconductor device.

Referring to FIG. 1A, a first inter-layer insulation layer 12 is formed over a substrate 11, and a plurality of bit lines are formed thereon. Each of the bit lines is formed by sequentially stacking a tungsten layer 13, and a bit line hard mask layer 14. A plurality of bit line spacers 15 are formed on sidewalls of each of the bit lines.

A second inter-layer insulation layer 16 is formed over the above resulting structure. The second inter-layer insulation layer 16 is selectively etched to form a storage node contact hole exposing a space between the bit lines. A conductive material fills the storage node contact hole to form a storage node contact plug 17.

An etch stop layer 18 and a storage node oxide layer 19 are sequentially formed and then, etched to form a storage node contact hole 20.

Particularly, the storage node oxide layer 19 is etched using a blanket etching process accompanying an over etching to secure a depth of the storage node contact hole 20. After the blanket etching process, the etch stop layer 18 formed beneath the storage node contact hole 20 is also etched to a predetermined thickness.

Referring to FIG. 1B, the etch stop layer 18 that remains beneath the storage node contact hole 20 is removed. As a result of this removal, the storage node contact plug 17 is exposed. Reference numerals 18A and 20A respectively represent a patterned etch stop layer and a storage node contact hole deeper than the previous storage node contact hole 20 after the above etching and removal.

However, as described above, in case that a mask is misaligned when a storage node contact hole is formed using a blanket etching process, an etch stop layer disposed beneath a storage node contact hole is often excessively etched, exposing a bit line hard mask to a greater extent.

As a distance between a storage node and a bit line decreases due to the current large scale integration, this undesirable excessive exposure may bring out an electric short circuit between the bit line and the storage node contact plug. This electric short circuit may induce various defects in a device.

### SUMMARY OF THE INVENTION

It is, therefore, an object of the present invention to provide a capacitor of a semiconductor device capable of reducing an electric short circuit between a bit line and a storage node contact plug due to excessive damage to an etch stop layer and a bit line hard mask during a storage node contact hole etching process, and a method for fabricating the same.

In accordance with one aspect of the present invention, there is provided a method for fabricating a capacitor of a semiconductor device, including: forming a first insulation layer over a substrate; forming a plug in the first insulation layer to contact the substrate; forming an etch stop layer and a second insulation layer over a resultant structure obtained after forming the plug; etching the second insulation layer to expose a portion of the etch stop layer; oxidizing the exposed portion of the etch stop layer; removing the oxidized portion of the etch stop layer by a wet cleaning process to form a contact hole exposing the plug; and forming a storage node over the contact hole.

In accordance with another aspect of the present invention, there is provided a method for fabricating a semiconductor device, including: forming a first insulation layer over a substrate; forming a plurality of bit lines over the first insulation layer; forming a second insulation layer over the bit lines; selectively etching the second insulation layer to form a first storage node contact hole exposing the substrate between neighboring bit lines; forming a storage node contact plug inside the first storage node contact hole; forming an etch stop layer over a resultant structure obtained after filling the storage node contact plug material; forming a third insulation layer over the etch stop layer; etching the third insulation layer to expose a portion of the etch stop layer; oxidizing the exposed portion of the etch stop layer; removing the oxidized portion of the etch stop layer by a wet cleaning process to form a second storage node contact hole exposing the storage node contact plug; and forming a storage node over the second storage node contact hole.

In accordance with a further aspect of the present invention, there is provided a method for fabricating a semiconductor device, including: preparing a substrate where a plug is already formed; forming an etch stop layer over the substrate; forming an insulation layer over the etch stop layer; etching the insulation layer to expose a portion of the etch stop layer; oxidizing the exposed portion of the etch stop layer; and removing the oxidized portion of the etch stop layer to form a contact hole exposing the plug.

### BRIEF DESCRIPTION OF THE DRAWINGS

The above and other objects and features of the present invention will become better understood with respect to the following description of the exemplary embodiments given in conjunction with the accompanying drawings, in which:

FIGS. 1A and 1B are cross-sectional views illustrating a typical method for fabricating a capacitor of a semiconductor device; and

FIGS. 2A to 2C are cross-sectional views illustrating a method for fabricating a capacitor of a semiconductor device in accordance with a specific embodiment of the present invention.

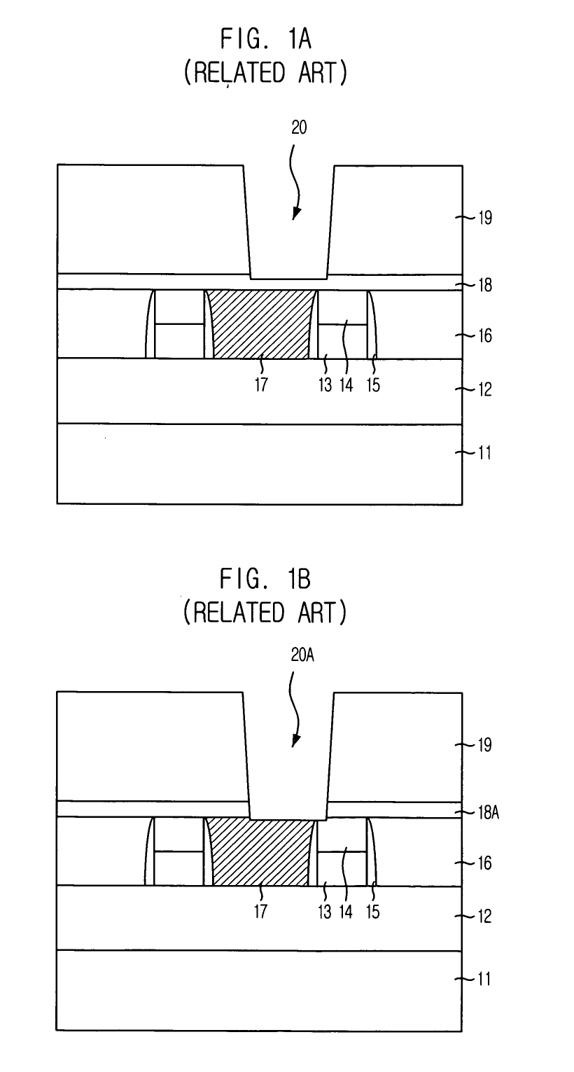

### DETAILED DESCRIPTION OF THE INVENTION

Hereinafter, detailed descriptions on certain embodiments of the present invention will be provided with reference to the accompanying drawings.

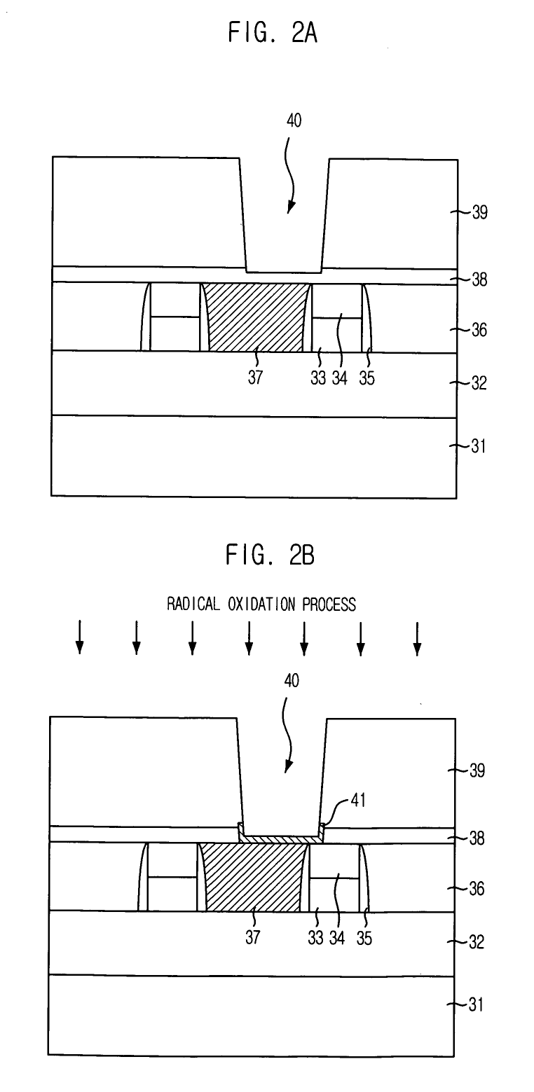

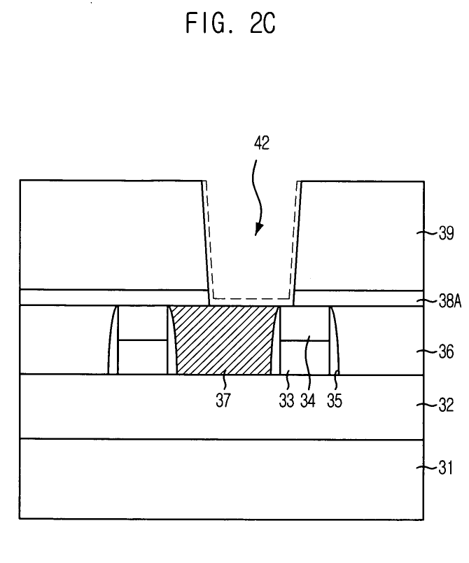

FIGS. 2A to 2C are cross-sectional views illustrating a method for fabricating a capacitor of a semiconductor device in accordance with a specific embodiment of the present invention.

As shown in FIG. 2A, a first inter-layer insulation layer 32 is formed over a substrate 31 and a plurality of bit lines are formed thereon. Each of the bit line is formed by sequentially stacking a bit line tungsten layer 33, and a bit line hard mask layer 34. A plurality of spacers 35 are formed over sidewalls of each of the bit lines.

A second inter-layer insulation layer 36 is formed over the resulting structure, and a storage node contact hole exposing a space between the bit lines is formed. A conductive layer fills the storage node contact hole to form a storage node contact plug 37. The storage node contact plug 37 typically includes polysilicon.

Before the formation of the storage node contact plug 37, a well process and processes required to form dynamic random access memory (DRAM) constitution including device isolation and word lines are performed.

An etch stop layer 38 and a storage node oxide layer 39 are sequentially formed. The storage node oxide layer 39 is formed with an oxide layer to form a cylinder type storage node hole, and the etch stop layer 38 serves a role as an etch barrier to prevent lower structures from being etched during a subsequent etching process on the storage node oxide layer 39.

The etch stop layer 38 is formed with a nitride layer, and the storage node oxide layer 39 is formed with one selected from a group consisting of a borophosphosilicate glass (BPSG) layer, an undoped silicate glass (USG) layer, a plasma enhanced tetraethylorthosilicate glass (PETEOS) layer and a high density plasma (HDP) oxide layer.

The storage node oxide layer 39 is etched to form a storage node contact hole 40. During etching the storage node oxide layer 39, the etch stop layer 38 formed beneath the storage node oxide layer 39 is also etched to a predetermined thickness by an over etching process.

As shown in FIG. 2B, the etch stop layer 38 exposed by the storage node contact hole 40 is oxidized using a radical oxidation process. Reference numeral 41 represent an oxidized etch stop layer.

In more detail, the radical oxidation process oxidizes a portion of the etch stop layer 38 up to where the storage node contact plug 37 is formed.

The radical oxidation process is performed using oxygen (O₂) gas, a mixture gas including O₂ and water (H₂O), or a mixture gas including hydrogen (H₂) and O₂. Also, the radical oxidation process is performed under a pressure ranging from approximately 0.5 mTorr to approximately 1.5 mTorr at approximately 500° C. to approximately 1,000° C. The radical oxidation process does not change the state of the storage node oxide layer 39 but oxidizes the portion of the etch stop layer 38 (e.g., the nitride layer) exposed by the storage node contact hole 40. Thus, the oxidation is performed up to the portion of the etch stop layer 38 where the storage node contact plug 37 is formed. As for the radical oxidation process, an oxidization rate becomes faster and an oxidization amount increases as the pressure gets lower.

As shown in FIG. 2C, a pre-cleaning process performed prior to forming a conductive layer for a storage node removes the oxidized etch stop layer 41. The cleaning process may be a wet cleaning process and using one of buffered oxide etchant (BOE) and hydrogen fluoride (HF) solution. After the cleaning process, the storage node contact plug 37 is exposed. Reference numeral 38A represents a patterned etch stop layer. The cleaning process is a typical cleaning process performed prior to forming a conductive layer for a storage node after a storage node contact hole is formed. Also, the cleaning process increases the area of the storage node contact hole 40. Reference numeral 42 represents an expanded storage node contact hole. As illustrated, the storage node contact plug 37 can be opened without damaging the etch stop layer 38.

Although not shown, as a subsequent process, a storage node can be formed over the storage node hole, and a dielectric layer and a plate electrode are sequentially formed over the storage node.

As described above, a wet etching process removes an oxidized portion of an etch stop layer in which a storage node contact plug is formed to prevent a bit line hard mask from being excessively etched. Accordingly, it is possible to increase a distance between a storage node and a bit line to increase a self aligned contact (SAC) margin.

In accordance with the present invention, a predetermined portion of an etch stop layer is oxidized during forming a storage node contact hole, and a wet etching process is performed to remove the oxidized portion of the etch stop. Accordingly, a bit line hard mask cannot be excessively etched.

Furthermore, since the wet etching process removes the oxidized portion of the etch stop layer, a line width of a storage node contact hole is increased to increase a capacitance of a storage node. Also, a distance between a bit line tungsten layer and a storage node is increased and thus, a self aligned contact (SAC) fail can be prevented.

The present application contains subject matter related to the Korean patent application No. KR 2005-0112366, filed in the Korean Patent Office on Nov. 23, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a capacitor of a semiconductor device, comprising:
forming a first insulation layer over a substrate;
forming a plug in the first insulation layer to contact the substrate;
forming an etch stop layer and a second insulation layer over a resultant structure obtained after forming the plug;
etching the second insulation layer to expose a portion of the etch stop layer;
oxidizing the exposed portion of the etch stop layer;
removing the oxidized portion of the etch stop layer by a wet cleaning process to form a contact hole exposing the plug; and
forming a storage node over the contact hole.

2. The method of claim 1, wherein the exposed portion of the etch stop layer is oxidized up to a portion thereof contacting the plug.

3. The method of claim 2, wherein the exposed portion of the etch stop layer is oxidized using a radical oxidation process.

4. The method of claim 3, wherein the radical oxidation process includes one of oxygen (O₂) and hydrogen (H₂).

5. The method of claim 3, wherein the radical oxidation process includes a pressure ranging from approximately 0.5 mTorr to approximately 1.5 mTorr, and a temperature ranging from approximately 500° C. to approximately 1,000° C.

6. The method of claim 3, wherein the radical oxidation process includes one selected from a group consisting of O₂ gas, a mixture gas including O₂ and water (H₂O), and a mixture gas including H₂ and O₂.

7. The method of claim 1, wherein the removing of the oxidized portion of the etch stop layer through the wet cleaning process includes one of buffered oxide etchant (BOE) and hydrogen fluoride (HF) solution.

8. The method of claim 3, wherein the etching of the second insulation layer is performed in a manner to expose a predetermined portion of the etch stop layer.

9. A method for fabricating a semiconductor device, comprising:
forming a first insulation layer over a substrate;
forming a plurality of bit lines over the first insulation layer;
forming a second insulation layer over the bit lines;
selectively etching the second insulation layer to form a first storage node contact hole exposing the substrate between neighboring bit lines;
forming a storage node contact plug inside the first storage node contact hole;
forming an etch stop layer over a resultant structure obtained after filling the storage node contact plug material;
forming a third insulation layer over the etch stop layer;
etching the third insulation layer to expose a portion of the etch stop layer;
oxidizing the exposed portion of the etch stop layer;
removing the oxidized portion of the etch stop layer by a wet cleaning process to form a second storage node contact hole exposing the storage node contact plug; and
forming a storage node over the second storage node contact hole.

10. The method of claim 9, wherein the exposed portion of the etch stop layer is oxidized up to a portion thereof contacting the plug.

11. The method of claim 10, wherein the exposed portion of the etch stop layer is oxidized using a radical oxidation process.

12. The method of claim 11, wherein the radical oxidation process includes one of O₂ and H₂.

13. The method of claim 11, wherein the radical oxidation process includes a pressure ranging from approximately 0.5 mTorr to approximately 1.5 mTorr, and a temperature ranging from approximately 500° C. to approximately 1,000° C.

14. The method of claim 13, wherein the radical oxidation process includes one selected from a group consisting of O₂, a mixture gas including O₂ and H₂O and a mixture gas including H₂ and O₂.

15. The method of claim 9, wherein the removing the oxidized portion of the etch stop layer by using the wet cleaning process includes one of BOE and HF solution.

16. The method of claim 11, wherein the etching of the third insulation layer is performed in a manner to recess a predetermined portion of the etch stop layer.

17. A method for fabricating a semiconductor device, comprising:
preparing a substrate where a plug is already formed;
forming an etch stop layer over the substrate;
forming an insulation layer over the etch stop layer;
etching the insulation layer to expose a portion of the etch stop layer;
oxidizing the exposed portion of the etch stop layer; and
removing the oxidized portion of the etch stop layer to form a contact hole exposing the plug.

18. The method of claim 17, wherein the exposed portion of the etch stop layer is oxidized up to a portion thereof contacting the plug.

19. The method of claim 18, wherein the exposed portion of the etch stop layer is oxidized using a radical oxidation process.

20. The method of claim 19, wherein the radical oxidation process includes one of O₂ and H₂.

21. The method of claim 20, wherein the radical oxidation process includes a pressure ranging from approximately 0.5 mTorr to approximately 1.5 mTorr, and a temperature ranging from approximately 500° C. to approximately 1,000° C.

22. The method of claim 21, wherein the radical oxidation process includes one selected from a group consisting of O₂, a mixture gas including O₂ and H₂O and a mixture gas including H₂ and O₂.

23. The method of claim 17, wherein the removing the oxidized portion of the etch stop layer by using the wet cleaning process includes one of BOE and HF solution.

24. The method of claim 19, wherein the etching of the insulation layer is performed in a manner to expose a predetermined portion of the etch stop layer.
